(19) United States
(12) Patent Application Publication
(10) Pub. No.: US 2015/0026528 A1
(43) Pub. Date: Jan. 22, 2015

(54) CONTROLLER BASED MEMORY EVALUATION

(71) Applicants: Manuel A. d'Abreu, El Dorado Hills, CA (US); Steve Skala, Fremont, CA (US)

(72) Inventors: Manuel A. d'Abreu, El Dorado Hills, CA (US); Steve Skala, Fremont, CA (US)

(21) Appl. No.: 13/943,516

(22) Filed: Jul. 16, 2013

(51) Int. Cl. G11C 29/44

(52) U.S. Cl. CPC G11C 29/44
USPC 714/718

(57) ABSTRACT

A memory system or flash card may include a controller. Improved testing and memory evaluation may be achieved by utilizing the memory's controller rather than an external tester. User defined test algorithms may be run from the controller to characterize, evaluate and test memory (e.g. NAND memory) or test other components, such as the controller itself.

### TECHNICAL FIELD

This application relates generally to evaluating memory storage. More specifically, this application relates to using the memory controller to evaluate and test non-volatile semiconductor flash memory.

### BACKGROUND

Non-volatile memory systems, such as solid-state or flash memory (e.g. NAND memory), have been widely adopted for use in consumer products. Flash memory may be found in different forms, for example in the form of a portable memory card that can be carried between host devices or as a solid state disk (SSD) embedded in a host device. The host may write data to the flash memory.

Memory testing and characterization may be necessary for evaluating the memory. However, due to the manufacturing process, it may be difficult to access the memory and testing may be difficult and require expensive testers and test programs. In particular, the chip may be manufactured such that the NAND is mounted on a product (e.g. a card), and may be inaccessible. Testing of the NAND may be difficult once the product is manufactured. In particular, the testing may require the host or host device to access the NAND through the pins (e.g. USB interface). Further, testing of the memory component may occur (before assembly in the card), and then after the memory is assembled onto a card, the card must be tested. Testing of assembled cards may require firmware related to the product. The availability of the firmware often delays the card testing.

### SUMMARY

Improved testing of NAND memory devices may be achieved through the use of the controller. The memory controller can be used rather than requiring an external tester or testing device. When the controller and NAND die reside inside the same package, then no direct access to the NAND die is required for testing and characterization of the NAND. The system may include a controller that communicates with the NAND. The controller may be programmed (through the host I/O's) to perform user defined operations on the NAND. The controller may collect data such as user programmed data, various parameters related to the NAND operations such as Erase, Program and Read that are used to run different tests on different NAND instances and collect data for statistical analysis. The system may support self-test at the product level when the NAND die and controller are packaged together. The NAND may be manufactured to reside inside the same package of the controller, and no direct access to the NAND is required. Also testing does not have to wait for the availability of the production firmware.

### BRIEF DESCRIPTION OF THE DRAWINGS

FIG. 1 is a block diagram of a host connected with a memory system having non-volatile memory.

FIG. 2 is a block diagram of an exemplary flash memory device controller for use in the system of FIG. 1.

FIG. 3 is a block diagram of an alternative exemplary memory system.

FIG. 4 is an example physical memory organization of the system of FIG. 1.

FIG. 5 is an expanded view of a portion of the physical memory of FIG. 4.

FIG. 6 is a diagram of inputs for the controller based memory evaluation.

FIG. 7 is a diagram of exemplary testing algorithms.

FIG. 8 is a chart for controller based memory evaluation.

FIG. 9 is a graphical user interface for controller based testing.

FIG. 10 is a graphical user interface for user defined algorithms in controller based testing.

FIG. 11 is a chart of an exemplary test using the controller.

FIG. 12 is a chart of another exemplary test using the controller.

### BRIEF DESCRIPTION OF THE PRESENTLY PREFERRED EMBODIMENTS

A memory system or flash card may include a controller. Improved testing and memory evaluation may be achieved by utilizing the memory's controller. User defined test algorithms may be run from the controller to test memory (e.g. NAND memory). The controller may be part of an application specific integrated circuit (“ASIC”) that acts as the tester. The controller may run application programs and exercise IP blocks internal to the controller. In the final product (e.g. card) that includes the controller, the controller can test the NAND die. The testing from the controller may improve product level diagnostics and failure analysis. The controller may enable functional test of the final product. The functional tests may be under different usage scenarios or under particular stress conditions (e.g. temperature, relaxation time, voltage) for product qualifications. There may be a NAND specific test and the test may be statistically based for identifying potential errors rather than testing the full NAND arrays. The test may target specific worst case conditions and support a debug of firmware. Special modes may be added to capture history and transactions. The testing may support error correction.

The controller may support multiple test algorithms. For example, the algorithms may be unique to the device and the usage pattern (e.g. a memory card for a camera which has larger files as compared with a memory card for a smartphone which may have a different usage pattern). The algorithms are not dependent on the production firmware and each individual card can test itself even before the production firmware is loaded (the firmware may be required for communications with the host, but the controller based testing can still be performed without the firmware). This controller testing supports a low cost tester and low cost device under test (“DUT”) management. All that the tester has to do is load and wait for test completion. This controller testing may increase parallel testing. NAND write/read throughput may be the limiting factor. The tests that may be targeted. For example, debugging may be improved when controller based because the card does not need to be disassembled (which may prevent error identification) to perform the debugging. The algorithm may be implemented as part of the testing or evaluation, the terms algorithm, testing, and evaluation may be used interchangeably throughout this disclosure. Besides testing, this system also allows data acquisition for flash devices using a very large sample size (number of devices). This may be critical for characterization and understanding the behavior of the flash device.

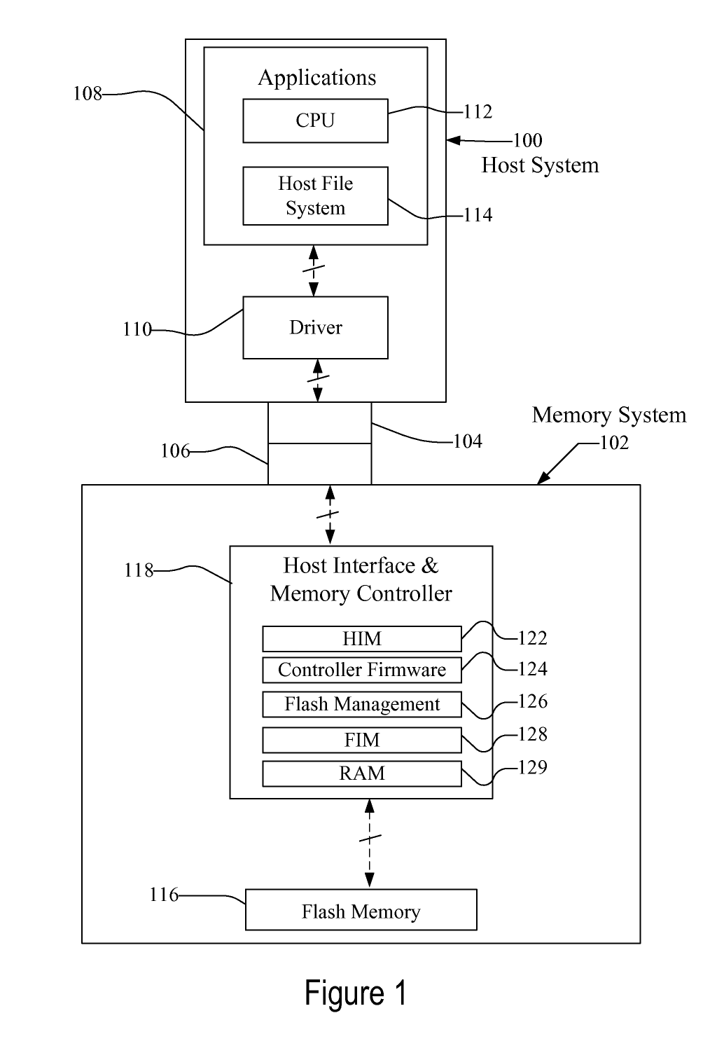

A flash memory system suitable for use in implementing aspects of the controller based memory evaluation is shown in FIGS. 1-5. A host system 100 of FIG. 1 stores data into and retrieves data from a flash memory 102. The flash memory may be embedded within the host, such as in the form of a solid state drive (SSD) drive installed in a personal computer. SSD may be any solid state disks such as NAND gate flash memory, NOR gate flash memory, 3D devices, stacked NAND, or any other nonvolatile solid state memories that may have a relatively limited life time due to wearing caused by write operations. Alternatively, the memory 102 may be in the form of a flash memory card that is removably connected to the host through mating parts 104 and 106 of a mechanical and electrical connector as illustrated in FIG. 1. A flash memory configured for use as an internal or embedded SSD drive may look similar to the schematic of FIG. 1, with one difference being the location of the memory system 102 internal to the host. SSD drives may be in the form of discrete modules that are drop-in replacements for rotating magnetic disk drives. As described, flash memory may refer to the use of a negated AND (NAND) cell that stores an electronic charge.

Examples of commercially available removable flash memory cards include the CompactFlash (CF), the MultiMediaCard (MMC), Secure Digital (SD), miniSD, Memory Stick, SmartMedia, TransFlash, and microSD cards. Although each of these cards may have a unique mechanical and/or electrical interface according to its standardized specifications, the flash memory system included in each may be similar. These cards are all available from SanDisk Corporation, assignee of the present application. SanDisk also provides a line of flash drives under its Cruzer trademark, which are hand held memory systems in small packages that have a Universal Serial Bus (USB) plug for connecting with a host by plugging into the host's USB receptacle. Each of these memory cards and flash drives includes controllers that interface with the host and control operation of the flash memory within them.

Host systems that may use SSDs, memory cards and flash drives are many and varied. They include personal computers (PCs), such as desktop or laptop and other portable computers, tablet computers, cellular telephones, smartphones, personal digital assistants (PDAs), digital still cameras, digital movie cameras, and portable media players. For portable memory card applications, a host may include a built-in receptacle for one or more types of memory cards or flash drives, or a host may require adapters into which a memory card is plugged. The memory system may include its own memory controller and drivers but there may also be some memory-only systems that are instead controlled by software executed by the host to which the memory is connected. In some memory systems containing the controller, especially those embedded within a host, the memory, controller and drivers are often formed on a single integrated circuit chip. The host may communicate with the memory card using any communication protocol such as but not limited to Secure Digital (SD) protocol, Memory Stick (MS) protocol and Universal Serial Bus (USB) protocol.

The host system 100 of FIG. 1 may be viewed as having two major parts, insofar as the memory device 102 is concerned, made up of a combination of circuitry and software. An applications portion 108 and/or a driver portion 110 may interface with the memory device 102. There may be a central processing unit (CPU) 112 and a host file system 114 implemented in hardware and the driver is implemented by firmware. In a PC, for example, the applications portion 108 is implemented in hardware that may include a processor 112 for running word processing, graphics, control or other popular application software. In a camera, cellular telephone or other host file system 114 that is primarily dedicated to performing a single set of functions, the applications portion 108 may be implemented in hardware for running the software that operates the camera to take and store pictures, the cellular telephone to make and receive calls, and the like.

The memory system 102 of FIG. 1 may include non-volatile memory, such as flash memory 116, and a memory controller 118 that both interfaces with the host 100 to which the memory system 102 is connected for passing data back and forth and controls the memory 116. The memory controller 118 may convert between logical addresses of data used by the host 100 and physical addresses of the flash memory 116 during data programming and reading. Functionally, the memory controller 118 may include a host interface module (HIM) 122 that interfaces with the host system controller logic 110, and controller firmware module 124 for coordinating with the host interface module 122, flash interface module 128, and flash management logic 126 for internal memory management operations such as garbage collection, and one or more flash interface modules (FIMs) 128 to provide a communication interface between the controller with the flash memory 116. The memory controller 118 may include random access memory (RAM) 129 in which certain data is temporarily stored. The memory controller 118 may include a processor for performing certain functions including the algorithms for evaluation discussed herein. The processor may be a part of the components shown in the memory controller 118, such as the HIM 122, firmware 124, flash management 126 and/or FIM 128. The algorithms may be stored in the RAM 129 of the memory controller or may be stored in the flash memory 116, which may include a certain portion of the memory 116 for storing the algorithms.

A flash transformation layer (“FTL”) or media management layer (“MML”) may be integrated in the flash management 126 and may handle flash errors and interfacing with the host. The FTL may be responsible for the internals of NAND management. In particular, the FTL may be an algorithm in the memory device firmware which translates writes from the host 100 into writes to the flash memory 116. The FTL may be needed because: 1) the flash memory may have limited endurance; 2) the flash memory 116 may only be written in multiples of pages; and/or 3) the flash memory 116 may not be written unless it is erased as a block. The FTL understands these potential limitations of the flash memory 116 which may not be visible to the host 100. Accordingly, the FTL attempts to translate the writes from host 100 into writes into the flash memory 116.

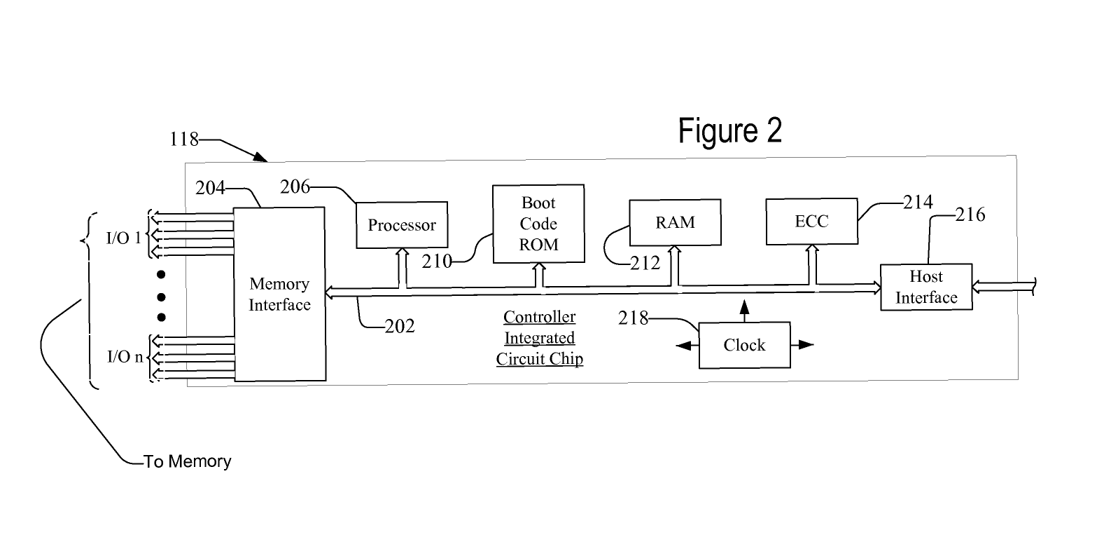

The memory controller 118 may be implemented on a single integrated circuit chip, such as an application specific integrated circuit (ASIC) such as shown in FIG. 2. The processor 206 of the memory controller 118 may be configured as a multi-thread processor capable of communicating via a memory interface 204 having I/O ports for each memory bank in the flash memory 116. The memory controller 118 may include an internal clock 218. The processor 206 communicates with an error correction code (ECC) module 214, a RAM buffer 212 (which may be the RAM 129 illustrated in FIG. 1), a host interface 216 (which may be the HIM 122 illustrated in FIG. 1), and boot code ROM 210 via an internal data bus 202.

The host interface 216 may provide the data connection with the host. The memory interface 204 may be one or more FIMs 128 from FIG. 1. The memory interface 204 allows the memory controller 118 to communicate with the flash memory 116. The RAM 212 may be a static random-access memory (“SRAM”). The ROM 210 may be used to initialize a memory system 102, such as a flash memory device. The memory system 102 that is initialized may be referred to as a card. The ROM 210 in FIG. 2 may be a region of read only memory whose purpose is to provide boot code to the RAM for processing a program, such as the initialization and booting of the memory system 102. The ROM may be present in the ASIC rather than the flash memory chip.

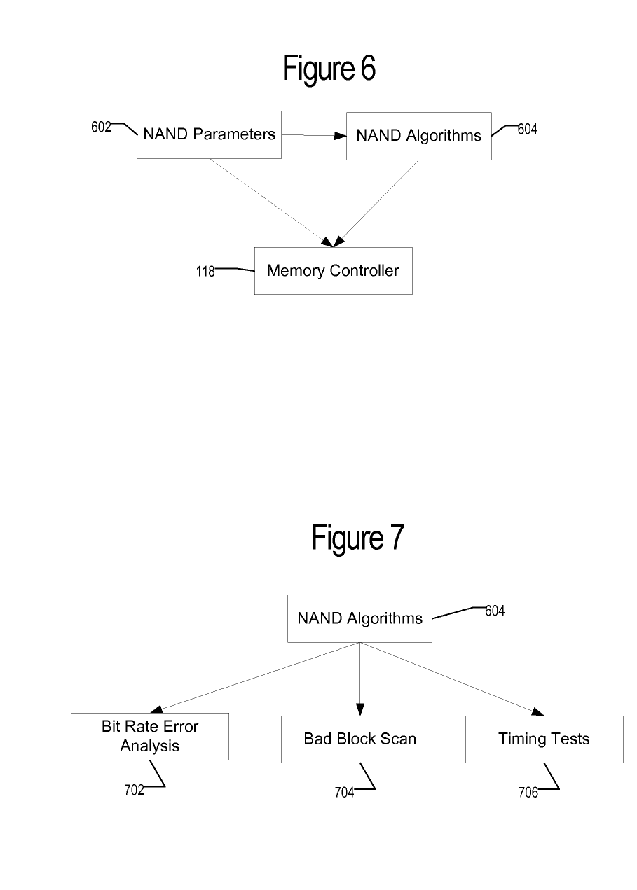

The memory controller 118 may include a testing algorithm that is run by the memory controller 118. In one embodiment, the host 100 loads the testing algorithm on to the memory system 102 to be run by the memory controller 118. However, the implementation of the testing algorithm may be performed solely by the memory controller 118 without an external tester and without the host. In other words, the testing is local to the memory system 102 as performed by the memory controller 118. The testing algorithms and implementation of the tests by the controller are further described below with respect to FIGS. 6-12.

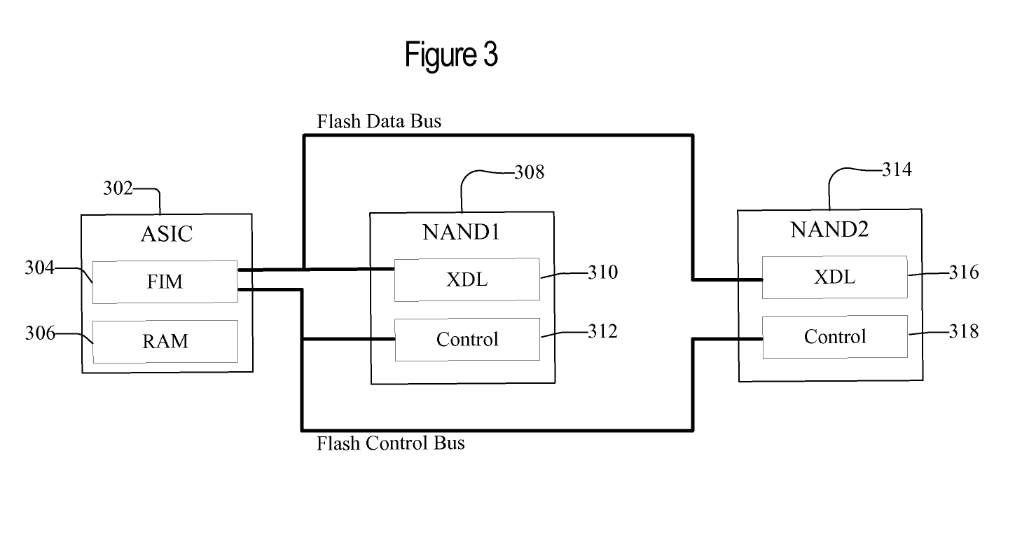

FIG. 3 is a block diagram of an alternative memory communication system. In particular, FIG. 3 illustrates multiple memories (NANDs) communicating over busses with a device, which is an application-specific integrated circuit (ASIC) 302 that may include a flash interface module (FIM) 304 and random access memory (RAM) 306. The ASIC 302 may be a chip that communicates with multiple flash memory modules or devices, such as NANDs 308, 314. The FIM 304 communicates data over the flash data bus and communicates control commands over the flash control bus. The NAND1 308 and NAND2 314 are types of flash memory that receive commands and data from the FIM 304 of the ASIC 302. Each of the NAND1 308 and NAND2 314 include controls 312, 318, respectively, for receiving control signals from the ASIC 302. Likewise, each of the NAND1 308 and NAND2 314 include an eXternal Data Latch (XDL) 310, 316, respectively, for receiving data signals from the ASIC 302. Although the flash data bus and flash control bus are illustrated as separate busses that communicate with the XDL 310, 316 and Control 312, 318 of the respective NANDs 308, 314, there may be a singular bus for communication. As described, a bitmap may be stored in the RAM 306 that is based on the FIM 304 accessing a source block from one of the the NANDs 308, 314. The bitmap stored in the RAM 306 is utilized for compaction by copying the source block to a destination block from one of the NANDs 308, 314.

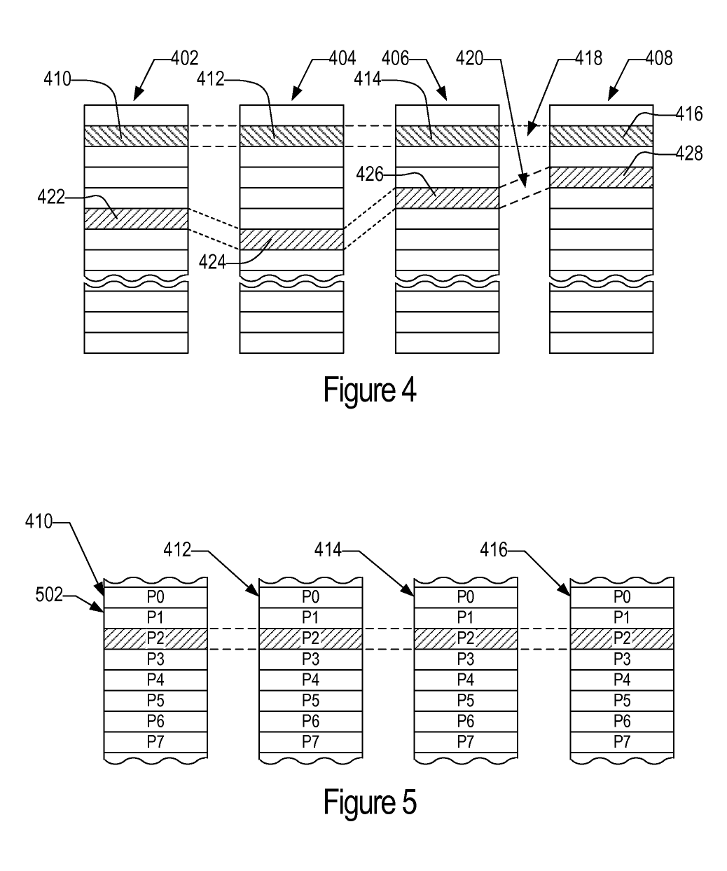

FIG. 4 conceptually illustrates an organization of the flash memory 116 (FIG. 1) as a cell array. The flash memory 116 may include multiple memory cell arrays which are each separately controlled by a single or multiple memory controllers 118. Four planes or sub-arrays 402, 404, 406, and 408 of memory cells may be on a single integrated memory cell chip, on two chips (two of the planes on each chip) or on four separate chips. The specific arrangement is not important to the discussion below. Of course, other numbers of planes, such as 1, 2, 8, 16 or more may exist in a system. The planes are individually divided into groups of memory cells that form the minimum unit of erase, hereinafter referred to as blocks. Blocks of memory cells are shown in FIG. 4 by rectangles, such as blocks 410, 412, 414, and 416, located in respective planes 402, 404, 406, and 408. There can be any number of blocks in each plane.

The block of memory cells is the unit of erase, and the smallest number of memory cells that are physically erasable together. For increased parallelism, however, the blocks may be operated in larger metablock units. One block from each plane is logically linked together to form a metablock. The four blocks 410, 412, 414, and 416 are shown to form one metablock 418. All of the cells within a metablock are typically erased together. The blocks used to form a metablock need not be restricted to the same relative locations within their respective planes, as is shown in a second metablock 420 made up of blocks 422, 424, 426, and 428. Although it is usually preferable to extend the metablocks across all of the planes, for high system performance, the memory system can be operated with the ability to dynamically form metablocks of any or all of one, two or three blocks in different planes. This allows the size of the metablock to be more closely matched with the amount of data available for storage in one programming operation.

The individual blocks are in turn divided for operational purposes into pages of memory cells, as illustrated in FIG. 5. The memory cells of each of the blocks 410, 412, 414, and 416, for example, are each divided into eight pages P0-P7. Alternatively, there may be 16, 32 or more pages of memory cells within each block. The page is the unit of data programming and reading within a block, containing the minimum amount of data that are programmed or read at one time. However, in order to increase the memory system operational parallelism, such pages within two or more blocks may be logically linked into metapages. A metapage 502 is illustrated in FIG. 4, being formed of one physical page from each of the four blocks 410, 412, 414, and 416. The metapage 502, for example, includes the page P2 in each of the four blocks but the pages of a metapage need not necessarily have the same relative position within each of the blocks. A metapage may be the maximum unit of programming.

The memory cells may be operated to store two levels of charge so that a single bit of data is stored in each cell. This is typically referred to as a binary or single level cell (SLC) memory. SLC memory may store two states: 0 or 1. Alternatively, the memory cells may be operated to store more than two detectable levels of charge in each charge storage element or region, thereby to store more than one bit of data in each. This latter configuration is referred to as multi-level cell (MLC) memory. For example, MLC memory may store four states and can retain two bits of data: 00 or 01 and 10 or 11. Both types of memory cells may be used in a memory, for example binary SLC flash memory may be used for caching data and MLC memory may be used for longer term storage. The charge storage elements of the memory cells are most commonly conductive floating gates but may alternatively be non-conductive dielectric charge trapping material. In implementations of MLC memory operated to store two bits of data in each memory cell, each memory cell is configured to store four levels of charge corresponding to values of “11,” “01,” “10,” and “00.” Each bit of the two bits of data may represent a page bit of a lower page or a page bit of an upper page, where the lower page and upper page span across a series of memory cells sharing a common word line. Typically, the less significant bit of the two bits of data represents a page bit of a lower page and the more significant bit of the two bits of data represents a page bit of an upper page.

FIG. 6 is a diagram of inputs for the controller based memory evaluation. In particular, the memory controller 118 receives one or NAND algorithms 604. The NAND algorithms 604 may be used for characterization, evaluation, or testing purposes. In one embodiment, the testing may be of the memory (e.g. the NAND). The NAND algorithms 604 may include NAND parameters 602 that are part of the testing. For example, testing of the memory may include parameters 602 such as bit rate, program time, erase time, read times, and/or write times. The memory for the device may be characterized and evaluated based on the testing.

Additional exemplary algorithms may utilize certain functions of the memory for system customization. The functions may include subroutines that perform functions or provide certain information about the memory being tested. In one embodiment, low level application program interfaces (“APIs”) may be performed for extracting certain information. The APIs may be considered to be NAND parameters 602. For example, there may be buffer manipulation routines, such as AllocateBuffer, FillBuffer, CombineBuffer, FillBufferPattern, FillBufferRandom, and/or DestroyBuffer. NAND “if” control routines may include StatusRead, GetID, Reset, Erase, ErasePlaneInterleave, Read, ReadPlaneInterleave, ChipEnable, NandDataOut, ReadCont, Program, and/or ProgramPlanInterleave. A result log may include results from error testing, such as LogErrorLog, BadBlocks, and/or BadColumn. There may also be high level APIs may be from once the test is generated. Exemplary high level APIs may include SinglePageRead, SingleBlockRead, IntermedaiteBlockRead, FullBlockRaed, SinglePageProgram, IntermedaitepageProgram, FullPageProgram, SingleBlockErase, IntermediateBlockErase, FullBlockErase, CompareSinglePage, CompareIntermediatePage, CompareFullPage, CompareSingleBuff, GetFactoryBadBlocks, and/or GetFactoryBadColumn.

FIG. 7 is a diagram of exemplary testing algorithms 604. Bit rate error analysis 702 may include ECC errors. A distribution of errors per cycle may be determined. For example, the number of bit errors per ECC page may be determined per cycle. ECC may be run from the controller or raw data may be collected by the controller and then bits in errors (and their locations) can be determined by other means such as software running externally. A bad block scan 704 may be used to determine bad blocks in the memory. Timing tests 706 may include erase/program/read timing tests. A minimum and maximum erase or read operation may be performed. As described, each of the exemplary algorithms 604 are tests stored on and performed by the memory controller. Although the examples in FIG. 7 illustrate tests for the memory, other tests may be performed by the controller for other components (e.g. the controller could test itself).

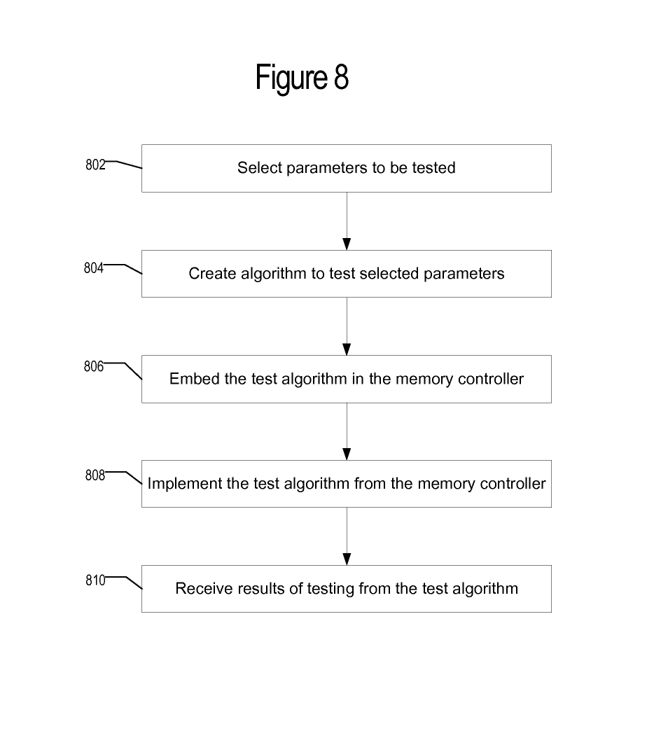

FIG. 8 is a chart for controller based memory evaluation. In block 802, parameters may be selected for testing. Based on those parameters to be tested, an algorithm may be generated in block 804. The algorithm may be embedded in the memory controller in block 806. In one embodiment, a host device may be used for transferring/downloading the algorithm to the memory controller. However, the host device is not needed when the algorithm is implemented by the memory controller in block 808. The algorithm may be any testing/evaluation (e.g. FIG. 7) programs that provide information about the memory. In another embodiment, the testing may be for components other than the memory (e.g. the memory controller tests itself). The results/information from the testing/evaluation may be outputted in block 810. In one embodiment, the results may be displayed on a graphical user interface. In another embodiment, the results may be stored in the memory itself, or loaded into a database

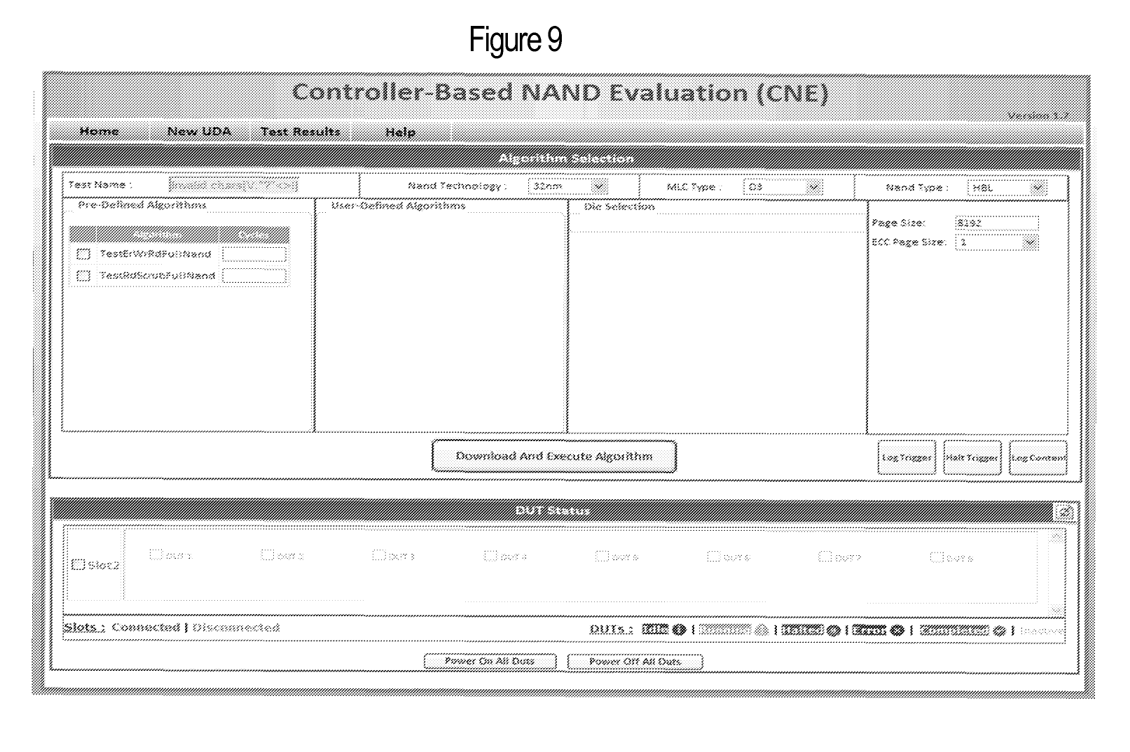

FIG. 9 is a graphical user interface (GUI) for controller based testing. The interface is one embodiment for downloading, accessing, and executing algorithms. The interface may run on a platform for controller based testing. There may be predefined algorithms or user-defined algorithms that are run selected die. The page size, ECC page size, NAND technology, MLC type and NAND type may be configurable parameters for the testing. This interface may be applicable to a plurality of memory devices such that particular algorithms can be downloaded and executed on multiple devices.

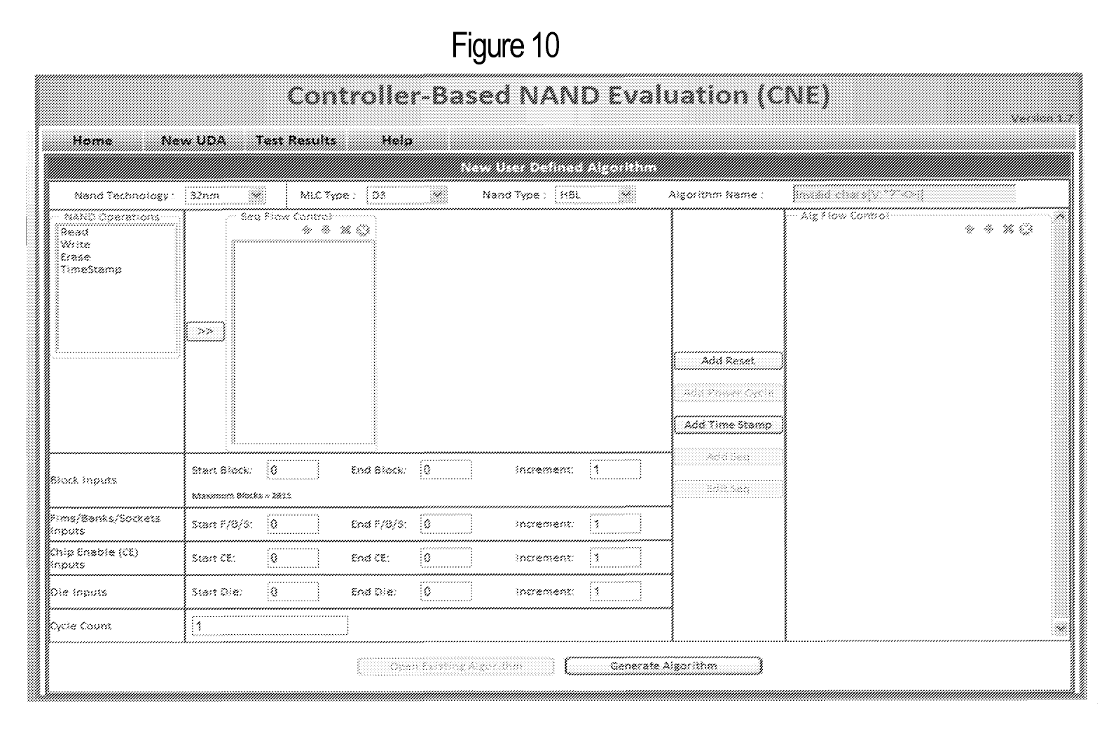

FIG. 10 is a graphical user interface for user defined algorithms in controller based testing. This interface is another embodiment of an exemplary user interface for generating and downloading testing/evaluation algorithms to the memory controller. In particular, the GUI may be used as a user defined algorithm definition page. Similar features to the GUI in FIG. 9 are present, but the user can select from certain NAND operations (e.g. Read, Write, Erase, TimeStamp) as well as block inputs, fims/banks/sockets inputs, chip enable inputs, die inputs and/or cycle count. This is an exemplary interface that may be used in the generation of a testing algorithm to be run off a memory controller.

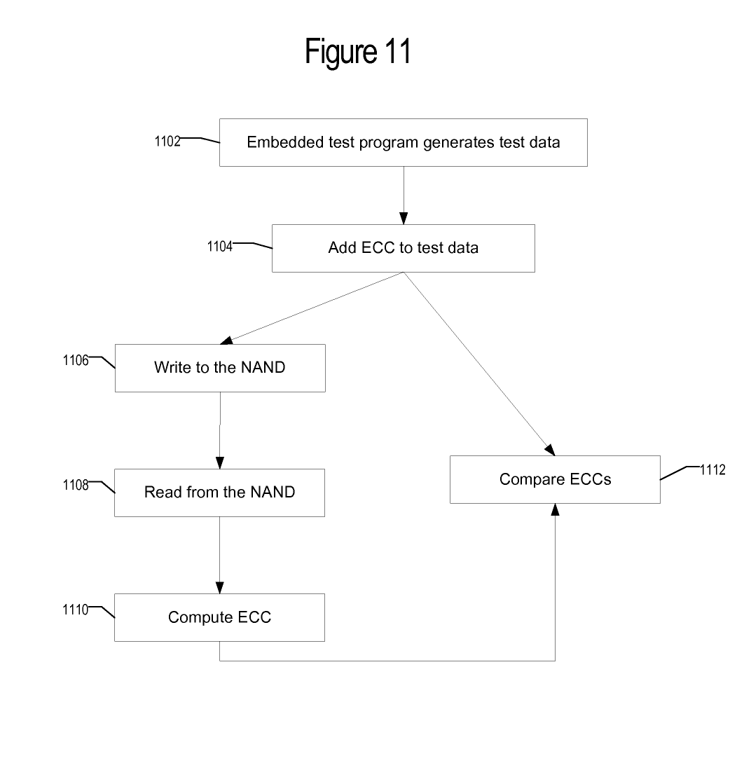

FIG. 11 is a chart of an exemplary test using the controller. In particular, FIG. 11 illustrates one test scenario. In block 1102, a test program or algorithm is embedded in the memory controller and generates data that is written (programmed) into the flash memory. ECC is then added to the test data in block 1104. A write is performed to the NAND in block 1106 and read is made from the NAND in block 1108. The ECC can then be computed in block 1110 based on the writing and reading in blocks 1106-1108. The computed ECC in block 1110 is then compared in block 1112 with the ECCs added to the test data in block 1104. The comparison can determine if there are any errors.

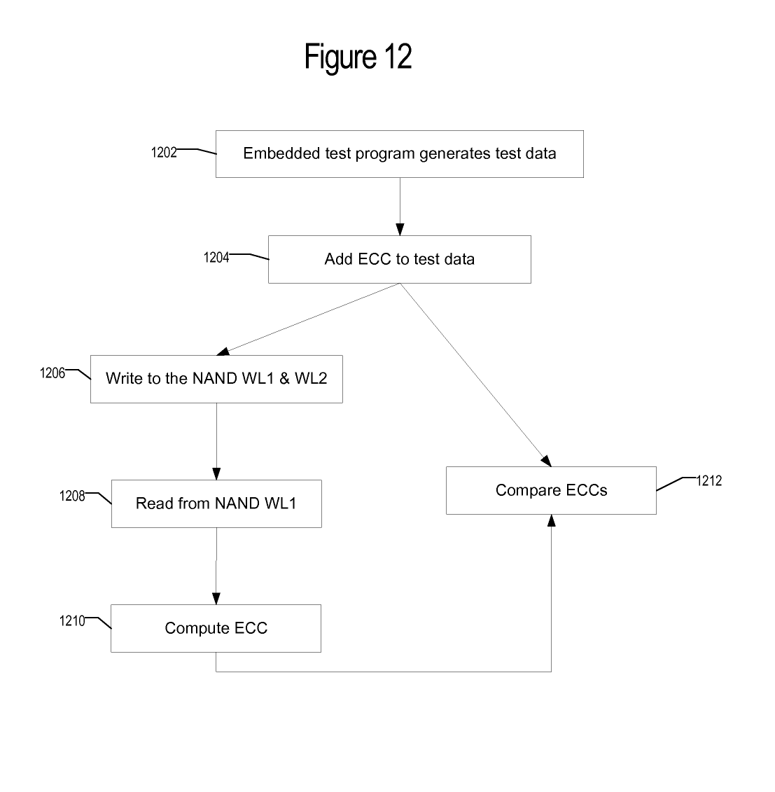

FIG. 12 is a chart of another exemplary test using the controller. In particular, FIG. 12 illustrates an embodiment in which each word line (WL) is tested by itself. In block 1202, a test program or algorithm is embedded in the memory controller and generates test data. ECC is then added to the test data in block 1204. A write is performed to two word lines (WL1 and WL2) in the NAND in block 1206. In block 1208, the first wordline WL1 is read from the NAND. The ECC can then be computed in block 1210 based on the writing and reading in blocks 1206-1208. The computed ECC in block 1210 is then compared in block 1212 with the ECCs added to the test data in block 1204. The comparison can determine if there are any errors.

The benefit of the two word line test in FIG. 12 is checking for errors in adjacent word lines. The test can check for any coupling between the two word lines because the writing of one word line may inject errors into a neighboring or adjacent wordline (e.g. because of the capacitive coupling). Accordingly, multiple word lines can be programed. The test may be to find out if the programming of word line one, generated an error in word line two, three, four, etc. FIG. 12 illustrates a test to determine if writing word line two (WL2) generated an error in word line one (WL1).

A “computer-readable medium,” “machine readable medium,” “propagated-signal” medium, and/or “signal-bearing medium” may comprise any device that includes, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. A non-exhaustive list of examples of a machine-readable medium would include: an electrical connection “electronic” having one or more wires, a portable magnetic or optical disk, a volatile memory such as a Random Access Memory “RAM”, a Read-Only Memory “ROM”, an Erasable Programmable Read-Only Memory (EPROM or Flash memory), or an optical fiber. A machine-readable medium may also include a tangible medium upon which software is printed, as the software may be electronically stored as an image or in another format (e.g., through an optical scan), then compiled, and/or interpreted or otherwise processed. The processed medium may then be stored in a computer and/or machine memory.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

We claim:

1. A flash memory device comprising:
a non-volatile storage having an array of memory blocks storing data; and
a controller in communication with the non-volatile storage, the controller is configured for:
receiving a test algorithm for testing the memory blocks; and
running one or more tests with the test algorithm on the memory blocks.

2. The device of claim 1 wherein the non-volatile storage comprises a NAND memory.

3. The device of claim 1 wherein the tests are run without needing a host device.

4. The device of claim 1 wherein the tests are run without an external tester.

5. The device of claim 1 wherein the test algorithm is embedded in the controller.

6. A flash memory device comprising:
a NAND memory storing data; and
a controller in communication with the NAND memory, the controller is configured for:
receiving NAND parameters and NAND algorithms; characterizing and
evaluating the NAND memory based on the NAND parameters and the NAND algorithms.

7. The device of claim 6 wherein the evaluating is accomplished without needing a host device.

8. The device of claim 6 wherein the evaluating is accomplished without an external tester.

9. A method for evaluating flash memory in a memory device comprising:
in the memory device having a controller and blocks of memory, the controller:
receiving a test program that is stored with the controller;
implementing the test program without a host device.

10. The method of claim 9 wherein the implementing of the test program is run by the controller independent of the host device.

11. The method of claim 9 wherein the implementing of the testing program is accomplished without an external tester.

12. The method of claim 9 wherein the flash memory comprises NAND memory.

13. The method of claim 9 wherein the testing program comprises one or more algorithms embedded in the controller.
